(19) United States
(12) Patent Application Publication
(10) Pub. No.: US 2008/0006525 A1
(43) Pub. Date: Jan. 10, 2008

(54) Non-Oxidised Electrolyte Electrochemical System

(75) Inventor: Xavier Fanton, Aulnay Sous Bois (FR)

Correspondence Address: OBLON, SPIVAK, MCCLELLAND MAIER & NEUSTADT, P.C., 1940 DUKE STREET, ALEXANDRIA, VA, 22314, US

(73) Assignee: SAINT-GOBAIN GLASS FRANCE, Courbevoie (FR)

(21) Appl. No.: 11/572,363

(22) PCT Filed: Jul. 19, 2005
(86) PCT No.: PCT/FR05/50593

§ 371 Date: Feb. 14, 2007

(30) Foreign Application Priority Data
Jul. 21, 2004 (FR) 0451601

(51) Int. Cl. H01M 6/14; B05D 5/12; C23C 14/24; C23C 14/34; G01N 27/407; G01N 27/416; G02F 1/153; H01M 6/04

(52) U.S. Cl. 204/192.17; 204/192.38; 204/414; 204/431; 359/270; 427/58; 427/77; 427/78; 429/188; 429/303

(57) ABSTRACT

Electrochemical system comprising at least one substrate, at least one electronically conductive layer, at least one electrochemically active layer capable of reversibly inserting ions, especially cations of the H⁺, Li⁺, Na⁺, K⁺, Ag⁺ type or OH⁻ anions, and at least one layer having an electrolyte function, characterized in that the electrolyte is transparent in the visible and comprises at least one layer made of an essentially mineral material, in nonoxidized form, the ionic conduction of which is generated or enhanced by the incorporation of one or more nitrogen compounds, in particular optionally hydrogenated or fluorinated nitride.

The present invention relates to the field of electrochemical devices comprising at least one electrochemically active layer capable of reversibly and simultaneously inserting ions and electrons, in particular to the field of electrochemical devices. These electrochemical devices are used especially for manufacturing glazing assemblies whose light and/or energy transmission or light and/or energy reflection can be modulated by means of an electric current. They may also be used to manufacture energy storage elements, such as batteries, or gas sensors.

Taking the particular example of electrochromic systems, it will be recalled that these comprise, in a known manner, at least one layer of a material capable of reversibly and simultaneously inserting cations and electrons, the oxidation states of which, corresponding to the inserted and extracted states, have different colors, one of the states generally being transparent.

Many electrochromic systems are constructed on the following “five-layer” model: TC1/EC1/EL/EC2/TC2, in which TC1 and TC2 are electronically conductive materials, EC1 and EC2 are electrochromic materials capable of reversibly and simultaneously inserting cations and electrons, and EL is an electrolyte material that is both an electronic insulator and an ionic conductor. The electronic conductors are connected to an external power supply and by applying a suitable potential difference between the two electronic conductors the color of the system can be changed. Under the effect of the potential difference, the ions are extracted from one electrochromic material and inserted into the other electrochromic material, passing through the electrolyte material. The electrons are extracted from one electrochromic material and enter the other electrochromic material via the electronic conductors and the external power circuit in order to counterbalance the charges and ensure electrical neutrality of the materials. The electrochromic system is generally deposited on a support, which may or may not be transparent, and organic or mineral in nature, which is then called a substrate. In certain cases, two substrates may be used—either each possesses part of the electrochromic system and the complete system is obtained by joining the two substrates together, or one substrate has the entire electrochromic system and the other one is designed to protect the system.

When the electrochromic system is intended to work in transmission, the electroconductive materials are generally transparent oxides, the electronic conduction of which has been increased by doping, such as the materials In₂O₃:Sn, In₂O₃:Sb, ZnO:Al or SnO₂:F. Tin-doped indium oxide (In₂O₃:Sn or ITO) is frequently chosen for its high electronic conductivity properties and its low light absorption. When the system is intended to work in reflection, one of the electroconductive materials may be of metallic type.

One of the electrochromic materials most used and most studied is tungsten oxide, which switches from a blue color to transparent depending on its insertion state. This is a cathodic coloration electrochromic material, that is to say its colored state corresponds to the inserted (or reduced) state and its bleached state corresponds to the extracted (or oxidized) state. During construction of a 5-layer electrochromic system it is common practice to combine it with an anodic coloration electrochromic material, such as nickel oxide or iridium oxide, the coloration mechanism of which is complementary. This results in an enhancement in the light contrast of the system. It has also been proposed to use a material that is optically neutral in the oxidization states in question, such as for example cerium oxide. All the abovementioned materials are of inorganic type, but it is also possible to combine organic materials, such as electronically conductive polymers (polyaniline, etc.) or Prussian blue, with inorganic electrochromic materials, or even to use only organic electrochromic materials. The cations are generally small monovalent ions, such as H⁺ and Li⁺, but it is also possible to use Ag⁺ or K⁺ ions.

The function of the electrolyte materials is to allow the reversible flow of ions from one electrochromic material to the other, while preventing the flow of electrons. It is generally expected that electrolytes will possess a high ionic conductivity and behave in a passive manner during flow of the ions. Their nature is adapted to the type of ions used for the electrochromic switching. The electrolytes may take the form of a polymer or a gel, for example a proton conduction polymer or a lithium ion conduction polymer. The electrolyte may also be a mineral layer, especially one based on tantalum oxide.

The choice of materials is guided by their optical properties but also by system cost, availability, processability and durability considerations. The terms “durable” and “durability” are used here in the sense of preserving the light properties of the systems over the entire period of their use.

When all the elements making up the electrochromic system are of inorganic nature, they are referred to as “all-solid” systems, such as those described in patent EP-0 867 752. When some of the materials are of inorganic nature and some of the materials are of organic nature, the systems are referred to as hybrid systems, such as those described in European patents EP-0 253 713 and EP 0-670 346, for which the electrolyte is a proton conduction polymer, or those described in patents EP-0 382 623, EP-0 518 754 or EP-0 532 408, for which the electrolyte is a lithium ion conduction polymer.

It is possible to insert an additional material between the electrolyte and at least one of the electrochromic materials, so as to modify the nature of the interface and/or to improve the durability of the system. The added material does not have to fulfill all the conditions usually expected of an electrolyte (for example possessing a lower electrical resistance or being an electrochromic material), the presence of the initial electrolyte guaranteeing that the multilayer or multi-material system thus created will favor the flow of ions, while preventing the flow of electrons. Such an example is available from patent EP-0 867 752 A1 relating to an all-solid electrochromic system in which a tungsten oxide layer has been inserted between the iridium oxide (the electrochromic material) and the tantalum oxide (the electrolyte). The same approach may be employed in the case of the hybrid system described in the article by K. S. Ahn et al., Appl. Phys. Lett. 81 (2002), 3930. The electrochromic materials are nickel hydroxide and tungsten oxide, and the electrolyte is a proton conduction solid polymer. An additional tantalum oxide layer has been inserted between each electrochromic material and the electrolyte polymer, since direct contact would degrade the electrochromic materials.

By extension, the multilayer or multi-material system thus created is called an electrolyte, as it does not participate in the ion insertion and extraction mechanism.

Such systems are described for example in European patents EP-0 338 876, EP-0 408 427, EP-0 575 207 and EP-0 628 849. At the present time, these systems can be put into two categories, depending on the type of electrolyte that they use:
either the electrolyte is in the form of a polymer or a gel, for example a proton conduction polymer, such as those described in European patents EP-0 253 713 and EP-0 670 346, or a lithium ion conduction polymer, such as those described in patents EP-0 382 623, EP-0 518 754 and EP-0 532 408;
or the electrolyte is a mineral layer, especially one based on tantalum oxide and/or tungsten oxide, which is an ionic conductor but an electronic insulator, the systems then being referred to as “all-solid” electrochromic systems.

The present invention relates more specifically to improvements made to electrochemical systems falling within the category of all-solid systems, but it is also intended for hybrid systems or even for systems in which all the components are of organic nature.

Document U.S. Pat. No. 5,552,242 discloses an electrochemical system of the all-solid battery type, the electrolyte of which consists of a hydrogenated silicon nitride.

Moreover, document EP 0 831 360 discloses the use of an electrolyte consisting of one or more layers, at least one electrochemically active layer of which, capable of reversibly inserting ions, especially cations of the H⁺, Li⁺, Na⁺ or Ag⁺ type, is based on an essentially mineral material, of the oxide type or OH⁻ anions.

In all these electrochemical devices, the ion insertion/extraction phenomena, and therefore the coloration/bleaching phenomena in the specific case of electrochromic systems, is satisfactorily reversible.

However, it turns out that, in use, the switching speed from one state to the other (coloration/bleaching in the specific case of electrochromic systems) is one of the operating parameters that could still be further improved with the aim of increasing the switching speed.

The object of the present invention is therefore to alleviate this drawback by providing an electrolyte for an electrochemical system that improves the switching speed.

For this purpose, the subject of the present invention is an electrochemical system comprising at least one substrate, at least one electronically conductive layer, at least one electrochemically active layer capable of reversibly inserting ions, especially cations of the H⁺, L_{I}⁺, Na⁺, K⁺, Ag⁺ type or OH⁻ anions, and at least one layer having an electrolyte function, characterized in that the electrolyte is transparent in the visible and comprises at least one layer made of an essentially mineral material, in nonoxidized form, the ionic conduction of which is generated or enhanced by the incorporation of one or more nitrogen compounds, in particular optionally hydrogenated or fluorinated nitrides or one or more fluorides.

By using such an electrolyte, the electrochemical system has a transition speed (speed of switching between a colored/bleached state and vice-versa) that is singularly improved over the electrochemical systems known from the prior art.

Moreover, it should be noted that the electrolyte according to the invention can be easily and rapidly deposited on a substrate by conventional sputtering techniques. Furthermore, the use of an electrolyte in an unoxidized form offers the advantage of singularly improving the durability of the electrochemical system.

Within the context of the invention, the abovementioned term “electrolyte” is a material or a combination of materials that will transfer ions reversibly inserted by the electrochemically active layer or layers of the system.

In other preferred embodiments of the invention, one or more of the following arrangements may optionally also be employed:
the layer having an electrolyte function is electronically insulating;
the layer having an electrolyte function has an absorption in the visible, for a 100 nm film, which is less than 20%, preferably less than 10% and even more preferably less than 5%;
the layer having an electrolyte function possesses a thickness of between 1 and 500 nm, preferably between 50 and 300 nm and even more preferably between 100 and 200 nm;
the layer having an electrolyte function is based on silicon nitride, boron nitride, aluminum nitride or zirconium nitride, by itself or as a mixture, and optionally doped;
the layer having an electrolyte function is a multilayer comprising, apart from the layer containing one or more nitrogen compounds, at least one other layer made of an essentially mineral material;
one of the other layers is selected from molybdenum oxide (WO₃), tantalum oxide (Ta₂O₅), antimony oxide (Sb₂O₅), nickel oxide (NiOₓ), tin oxide (SnO₂), zirconium oxide (ZrO₂), aluminum oxide (Al₂O₃), silicon oxide (SiO₂) niobium oxide (Nb₂O₅), chromium oxide (Cr₂O₃), cobalt oxide (Co₃O₄), titanium oxide (TiO₂), zinc oxide (ZnO), optionally alloyed with aluminum, and tin zinc oxide (SnZnOₓ), vanadium oxide (V₂O₅), at least one of these oxides being optionally hydrogenated or nitrided;
the layer having an electrolyte function is a multilayer comprising, apart from the layer containing one or more nitrogen compounds, at least one other layer made of a polymer material;
the layer having an electrolyte function is a multilayer comprising, apart from the layer containing one or more nitrogen compounds, at least one other layer based on molten salts;
one of the other layers is selected from polymers possessing ionic conduction properties, especially H⁺, L_{I}⁺, Ag⁺, K⁺ and Na⁺;
the other layer of the polymer type is selected from the family of polyoxyalkylenes, especially polyoxyethylene, or from the family of polyethyleneimines;
the other layer of the polymer type is in the form of an anhydrous or aqueous liquid or is based on one or more gels, or on one or more polymers, especially an electrolyte of the layer type comprising one or more hydrogen-containing and/or nitrogen-containing compounds of the POE:H₃PO₄ type or else a layer comprising one or more hydrogen-containing and/or nitrogen-containing compounds/PEI:H₃PO₄ or even more a laminatable polymer; and
the electrochemically active layer comprises at least one of the following compounds: tungsten (W) oxide, niobium (Nb) oxide, tin (Sn) oxide, bismuth (Bi) oxide, vanadium (V) oxide, nickel (Ni) oxide, iridium (Ir) oxide, antimony (Sb) oxide, and tantalum (Ta) oxide, by itself or as a mixture, and optionally including an additional metal, such as titanium, tantalum or rhenium.

The electrochemical device incorporating in its electrolyte at least one layer according to the invention may be designed so that the electrolyte is in fact a multilayer.

As a variant, the multilayer incorporating at least the nitrided layer includes other layers of the polymer type, which is in the form of a polymer or a gel, for example a proton conduction polymer, such as those described in European patents EP-0 253 713 and EP-0 670 346, or a lithium ion conduction polymer, such as those described in patents EP-0 382 623, EP-0 518 754, EP-0 532 408. It may also be an interpenetrating network polymer, as described in the application FR-A-2 840 078.

Thus, the electrolyte may be a multilayer electrolyte and may contain layers of solid material or in polymer form. The monolayer or multilayer electrolyte of the invention has a thickness of at most 5 μm and is especially of the order of 1 nm to 1 μm, in particular for electrochromic glazing applications.

Within the context of the invention, the term “solid material” is understood to mean any material having the mechanical strength of a solid, in particular any essentially mineral or organic material or any hybrid material, that is to say one that is partly mineral and partly organic, such as the materials that can be obtained by sol-gel deposition from organomineral precursors.

It therefore results in what is called an “all-solid” system configuration, which has a clear advantage in terms of manufacturability. This is because, when the system contains an electrolyte in the form of a polymer that does not have the mechanical strength of a solid for example, this means in fact that two “half-cells” have to be manufactured in parallel, each consisting of a carrier substrate coated with an electronically conductive first layer and then with an electrochemically active second layer, these two half-cells then being assembled with the electrolyte inserted between them. With an “all-solid” configuration, the manufacture is simplified since it is possible to deposit all the layers of the system, one after the other, on a single carrier substrate. The device is also lightened, since it is no longer essential to have two carrier substrates. The invention also relates to all the applications of the electrochemical device that has been described, in particular the following three applications:
the first application relates to electrochromic glazing. In this case, when the glazing is intended to operate in variable light transmission mode, it is advantageous for the substrate(s) of the device to be transparent, whether made of glass or plastic. If it is desired to give the glazing a mirror function, and to make it operate in variable light reflection mode, several solutions are possible: either one of the substrates is chosen to be opaque and reflective (for example a metal plate), or the device is combined with an opaque and reflective element, or one of the electronically conductive layers of the device is chosen to be of metallic nature and sufficiently thick to be reflective.

Especially when the glazing is intended to operate in variable light transmission mode with a device provided with one or two transparent substrates, it may be mounted as a multiple glazing unit, especially as a double-glazing unit, with another transparent substrate, and/or as a laminated glazing unit:
the second application relates to energy storage elements, most particularly to batteries incorporating especially hydrides, that can be used for example in any equipment involving electronic and/or computing means, and any equipment requiring an energy storage device that is intrinsic thereto, whether autonomous or not, or else as material for the production of obscuring windows, when this nitrided electrolyte is associated with materials whose switching is accompanied by the formation or the decomposition of a hydride of Ti, V, Cr, Mn, Fe, Gd, Ni, Cu, Zn, Zr, Nb, Mo, Tc, Ru, Rh, Pd, Ag, Cd, Hf, Ta, W, Re, Os, Ir, Pt, Au, Hg or Mg, by itself or as a mixture, optionally alloyed with Gd; and
the third application relates to gas sensors. These gas sensors may be used in particular in an industrial or commercial or domestic environment, as means for controlling or monitoring physical, chemical or physico-chemical measurement instruments.

Returning to the first application, that of electrochromic glazing, this may advantageously be employed as windows for buildings or for automobiles, windows for commercial/mass-transit vehicles, windows for land, air, river or sea transport, as driving mirrors or other mirrors, or as optical elements, such as camera lenses, or else as front face or element to be placed on or near the front face of display screens for equipment such as computers or televisions.

It has proved to be preferential, especially in the electrochromic glazing application, to have a laminated structure of the type: transparent substrate (glass, PC, PMMA, PET, etc.)/functional multilayer/polymer interlayer/transparent substrate (glass, PC, PMMA, PET, etc.).

If the substrates are made of glass, they may be made of clear or dark glass, they may be flat or curved in shape and they may be reinforced by chemical or thermal toughening, or simply hardened. Their thickness may vary between 1 mm and 19 mm, depending on the expectations and requirements of the final users. The substrates may be partially coated with an opaque material, in particular around their periphery, particularly for esthetic reasons. The substrates may also possess an intrinsic functionality (coming from a multilayer consisting of at least one layer of the solar-control, antireflection, low-emissivity, hydrophobic, hydrophilic or other type) and in this case the electrochromic glazing assembly combines the functions provided by each element so as to meet the requirements of users.

The polymer insert is used here for the purpose of joining the two substrates together by the lamination procedure widely used in the automobile or building fields, so as to end up with a security or comfort product: bulletproof or anti-ejection security, for use in the transport field, and anti-theft security (shatterproof glass) for use in the building field or, thanks to this lamination insert, providing an acoustic, solar-protection or coloration functionality. The lamination operation is also favorable in the sense that it isolates the functional multilayer from chemical or mechanical attack. The interlayer is preferably chosen to be based on ethylene/vinyl acetate (EVA) or on its copolymers, and it may also be made of polyurethane (PU), polyvinyl butyral (PVB), or a one-component or multicomponent resin that can be heat-cured (epoxy or PU) or UV-cured (epoxy or acrylic resin). The lamination insert is generally transparent, but it may be completely or partly colored in order to meet the wishes of users.

The isolation of the multilayer from the outside is generally completed by systems of seals placed along the end faces of the substrates, or indeed partly inside the substrates.

The lamination insert may also include additional functions, such as a solar-protection function provided for example by a plastic film comprising ITO/metal/ITO multilayers or a film composed of an organic multilayer.

The devices of the invention when used as a battery may also be employed for the building or vehicle fields, or they may form part of equipment of the computer, television or telephone type.

The invention also relates to processes for manufacturing the device according to the invention, in which the electrolyte layer of the invention that forms part of the electrolyte may be deposited by a vacuum technique, of the cathode sputtering type, possibly magnetically enhanced sputtering, by thermal evaporation or electron beam evaporation, by laser ablation, by CVD (Chemical Vapor Deposition), optionally plasma-enhanced or microwave-enhanced CVD.

The electrolyte layer of the invention forming part of the electrolyte may be deposited by an atmospheric-pressure technique, in particular by the deposition of layers by sol-gel synthesis, especially dip coating, spray coating or flow coating, or by atmospheric-pressure plasma CVD.

It is also possible to use a powder or liquid-phase pyrolysis technique or a CVD-type gas phase pyrolysis technique, but at atmospheric pressure.

In fact, it is particularly advantageous here to use a vacuum deposition technique, especially of the sputtering type, as the characteristics of the layer constituting the electrolyte (deposition rate, density, structure, etc.) may thereby be very finely controlled.

Thus, it is possible to deposit the electrolyte layer by reactive cathode sputtering in an atmosphere containing nitrogen compounds or their precursors. Within the context of the invention, the term “precursors” is understood to mean molecules or compounds that are capable of interacting and/or decomposing under certain conditions in order to form the desired nitrogen compound in the layer.

To deposit an electrolyte layer according to the invention that is nitrided, a gaseous precursor, especially one based on NH₃, or more generally a nitrogen-based precursor, especially in the form of an amine, imine, hydrazine or N₂, can be introduced into the sputtering chamber.

The electrolyte layer according to the invention may also be deposited by thermal evaporation, as mentioned above. It may be electron beam evaporation, the hydrogen and/or nitrogen compounds or their precursors being introduced into the layer in gaseous form and/or being contained in the material intended to be evaporated.

The electrolyte layer according to the invention may also be deposited by a sol-gel technique. The content of hydrogen and/or nitrogen compounds is controlled by various means: it is possible to adapt the composition of the solution, so that it contains these compounds or their precursors, or the composition of the atmosphere in which the deposition takes place. It is also possible to refine this control, by adjusting the deposition/curing temperature of the layer.

Other advantageous features and details of the invention will emerge from the description given below with reference to the appended drawings which represent:

FIG. 1 is a front view of the face 2 according to the invention;

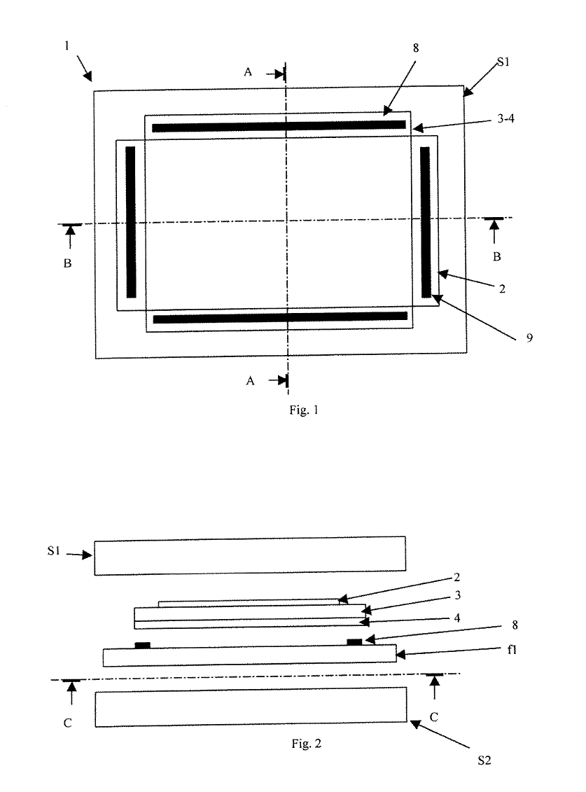

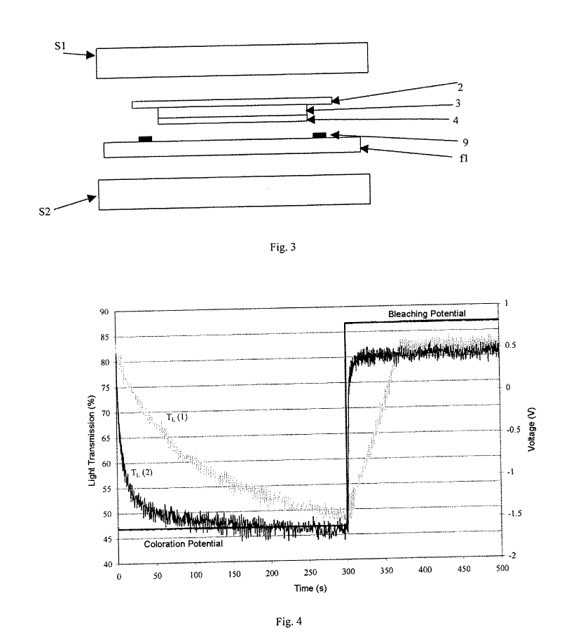

FIG. 2 is a sectional view on AA of FIG. 1;

FIG. 3 is a sectional view on BB of FIG. 1;

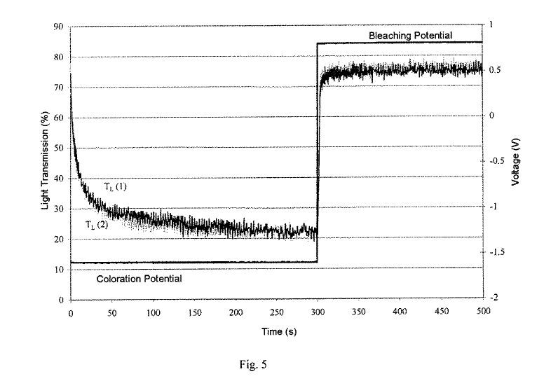

FIG. 4 shows a graph illustrating the switching speed of an electrochemical system according to the prior art compared with that of an electrochemical system that incorporates an electrolyte according to the invention; and

FIG. 5 shows a graph illustrating the influence of an electrolyte according to the invention on the switching speed.

In the appended drawings, certain elements have been shown on a larger or smaller scale than in reality, so as to make it easier to understand the figures.

The example illustrated by FIGS. 1, 2 and 3 relates to an electrochromic glazing unit 1. It comprises, in succession from the outside of the passenger compartment inward, two glass panes S1, S2 which are made of clear (but possibly also tinted) soda-lime silicate glass, for example of 2.1 mm and 2.1 mm thickness respectively.

The panes S1 and S2 are of the same size, with dimensions of 150 mm×150 mm.

The pane S1 shown in FIGS. 2 and 3 has, on face 2, a thin-film multilayer of the all-solid electrochromic type.

The pane S1 is laminated to the pane S2 via a thermoplastic sheet f1 of polyurethane (PU) 0.8 mm in thickness (this may be replaced with a sheet of ethylene/vinyl acetate (EVA) or polyvinyl butyral (PVB)).

The “all-solid” electrochromic thin-film multilayer comprises an active multilayer 3 placed between two electronically conductive materials, also called current collectors 2 and 4. The collector 2 is intended to be in contact with the face 2.

The collectors 2 and 4 and the active multilayer 3 may be either substantially of the same size and shape, or substantially of different size and shape, and it will be understood therefore that the path of the collectors 2 and 4 will be tailored according to the configuration. Moreover, the dimensions of the substrates, in particular S1, may be essentially greater than those of 2, 4 and 3.

The collectors 2 and 4 are of the metallic type or of the TCO (Transparent Conductive Oxide) type made of ITO, SnO₂:F or ZnO:Al, or they may be a multilayer of the TCO/metal/TCO type, this metal being selected in particular from silver, gold, platinum and copper. They may also be a multilayer of the NiCr/metal/NiCr type, the metal again being selected in particular from silver, gold, platinum and copper.

Depending on the configuration, they may be omitted, and in this case current leads are directly in contact with the active multilayer 3.

The glazing unit 1 incorporates current leads 8, 9 which control the active system via a power supply. These current leads are of the type used for heated windows (namely shims, wires or the like).

A first preferred embodiment of the collector 2 is one formed by depositing, on the face 2, a 50 nm thick SiOC first layer followed by a 400 nm thick SnO₂:F second layer (two layers being preferably deposited in succession by CVD on the float glass before cutting).

A second embodiment of the collector 2 is one formed by depositing, on face 2, a doped (especially aluminum-doped or boron-doped) or undoped bilayer consisting of a SiO₂-based first layer about 20 nm in thickness followed by an ITO second layer of about 100 to 600 nm in thickness (two layers preferably being deposited in succession, under vacuum, by reactive magnetron sputtering in the presence of oxygen and optionally carried out hot).

Another embodiment of the collector 2 is one formed by depositing, on face 2, a monolayer consisting of ITO about 100 to 600 nm in thickness (a layer preferably deposited, under vacuum, by reactive magnetron sputtering in the presence of oxygen and optionally carried out hot).

The collector 4 is a 100 to 500 nm ITO layer also deposited by reactive magnetron sputtering on the active multilayer.

The active multilayer 3 shown in FIGS. 2 and 3 is made up as follows:
a 100 to 300 nm layer of anodic electrochromic material made of nickel oxide, possibly alloyed with other metals. As a variant (not shown in the figures), the layer of anodic material is based on a 40 to 100 nm layer of iridium oxide;
a 100 nm layer of tungsten oxide;
a 100 nm layer of hydrated tantalum oxide or hydrated silica oxide or hydrated zirconium oxide, or a mixture of these oxides; and
a layer of cathodic electrochromic material based on hydrated tungsten oxide with a thickness of 200 to 500 nm, preferably 300 to 400 nm, for example about 370 nm.

The active multilayer 3 may be incized over all or part of its periphery with grooves produced by mechanical means or by laser etching, possibly using a pulsed laser. This is done so as to limit the peripheral electrical leakage, as described in French application FR-2 781 084.

The glazing unit shown in FIGS. 1, 2 and 3 also incorporates (but not shown in the figures) a first peripheral seal in contact with faces 2 and 3, this first seal being designed to form a barrier to external chemical attack.

A second peripheral seal is in contact with the edge of S1, the edge of S2 and the face 4 so as to form a barrier and a means of mounting the glazing in a vehicle, to provide a seal between the inside and the outside, to form an attractive feature, and to form means for the incorporation of reinforcing elements.

FIG. 4 (cf. curve 1) shows the variation in light transmission measured at the center of the glazing when it is subjected to a coloration/bleaching cycle by means of a voltage pulse.

If this active multilayer is supplied with a voltage pulse, it is found that the glazing, with an electrolyte according to the prior art, takes about 80 s to switch from a colored state to a bleached state (the reader may refer to FIG. 4).

On the basis of this same active multilayer, if at least one of the oxide-based layers constituting the electrolyte is substituted with a layer according to the teachings of the invention, that is to say a layer with a thickness of between 10 nm and 300 nm, made of silicon nitride, boron nitride, aluminum nitride or zirconium nitride, by itself or as a mixture, and optionally doped, it is then found that the glazing switches from a colored state to a bleached state in less than 15 s, for the same voltage pulse, all other things being equal. It is also noted that the coloration rate is greater (see the slope at the origin, which is very pronounced in curve 2).

FIG. 5 shows the variation in measured light transmission at the center of the glazing as a function of time, this glazing comprising an active multilayer structure in accordance with that described above, for which the electrolyte layer is either a monolayer according to the teachings of the invention (curve 1) or a bilayer based on a mineral oxide and on an electrolyte layer according to the teachings of the invention (curve 2).

The predominant influence of the nitride layer on the speed of switching between a colored state and a bleached state of the active system, whether or not the layer according to the invention is associated with a layer based on a mineral oxide, may therefore be noted.

According to yet another embodiment of the invention, the electrolyte layer is inserted according to the teachings of the invention between two mineral-oxide-based electrolyte layers. Thus, it is possible to have for example Ta₂O₅/the layer according to the invention/Ta₂O₅.

According to other variants, the “all-solid” active multilayer 3 may be replaced with other families of polymer-type electrochromic materials.

Thus, for example, a first part formed from a layer of electrochromic material, otherwise called the active layer, made of poly(3,4-ethylenedioxythiophene) from 10 to 10 000 nm, preferably 50 to 500 nm, in thickness—as a variant, it may be one of the derivatives of this polymer—is deposited by known liquid deposition techniques (spray coating, dip coating, spin coating or flow coating) or else by electrodeposition, on a substrate coated with its current collector, this current collector possibly being a lower or upper conducting layer forming the electrode (anode or cathode) optionally provided with wires or the like. Whatever the polymer constituting this active layer, this polymer is particularly stable, especially under UV, and operates by insertion/extraction of lithium ions (Li⁺) or alternatively of H⁺ ions.

A second part acting as electrolyte, and formed from a layer with a thickness of between 50 nm and 2000 μm, and preferably between 50 nm and 1000 μm, is deposited by a known liquid deposition technique (spray coating, dip coating, spin coating or flow coating) between the first and third parts on the first part, or else by injection. This second part is based on a polyoxyalkylene, especially polyoxyethylene. As a variant, it may be a mineral-type electrolyte based for example on hydrated tantalum oxide, zirconium oxide or silicon oxide.

This second electrolyte part deposited on the layer of active electrochromic material, which is itself supported by the glass or similar substrate, is then coated with a third part, the constitution of which is similar to the first part, namely this third part is made up of a substrate, coated with a current collector (conducting wires; conducting wires+conductive layer; conductive layer only), this current collector itself being covered with an active layer.

On the basis of this all-polymer electrochromic multilayer, it is proposed to substitute one of the electrolyte-forming layers with at least one layer having a similar function but according to the teachings of the invention. A layer according to the teachings of the invention is inserted between one of the active layers and one of the electrolyte-forming layers or in the middle of the electrolyte-forming layers.

According to yet another embodiment, it is proposed to replace one of the electrolyte-forming oxide layers in a hybrid (solid/polymer) multilayer with an unoxidized layer according to the invention or to insert an unoxidized layer according to the invention between the inorganic active material or materials and the polymer acting as electrolyte. As in the previous example, this insertion may be according to one of the following configurations:
a layer according to the teachings of the invention between one of the active layers and one of the electrolyte-forming layers or
in the middle of the electrolyte-forming layers.

This example corresponds to glazing that operates by proton transfer. It consists of a first glass substrate 1, made of soda-lime silicate glass 4 mm in thickness, followed in succession by:
a 300 nm electronically conductive first SnO₂:F layer;
a 185 nm anodic first layer of electrochromic material made of hydrated nickel oxide NiOₓH_{y} (it could be replaced with a 55 nm layer of hydrated iridium oxide);
an electrolyte made up of a 70 nm first layer of hydrated tantalum oxide, a 100 micron second layer of a POE/H₃PO₄ polyoxyethylene/phosphoric acid solid solution, or alternatively a PEI/H₃PO₄ polyethyleneimine/phosphoric acid solid solution;
a 350 nm second layer of cathodic electrochromic material based on tungsten oxide; and
a 300 nm second SnO₂:F layer followed by a second glass substrate identical to the first.

In this example, there is therefore a bilayer electrolyte based on a polymer normally used in this type of glazing, which is “lined” with a layer of tantalum hydroxide which is sufficiently conducting not to impair proton transfer via the polymer and which protects the back electrode made of anodic electrochromic material from direct contact with the latter, the intrinsic acidity of which would be prejudicial thereto.

Instead of the hydrated Ta₂O₅ layer, a layer of the hydrated Sb₂O₅ or TaWOₓ type may be used.

It is also possible to provide a three-layer electrolyte, with two hydrated oxide layers, either with one of them on each side of the polymer layer, or with the two layers superposed one on the other on the side facing the layer of anodic electrochromic material.

On the basis of this example, at least one of the layers having an electrolyte function based on tantalum oxide, antimony oxide or tungsten oxide is replaced with at least one layer of unoxidized electrolyte according to the invention. A layer of unoxidized electrolyte according to the invention may also be inserted between the layer of cathodic electrochromic material and the POE/H₃PO₄ or PEI/H₃PO₄ solid solution.

According to another variant, the layer according to the invention is inserted into a POE/H₃PO₄ or PEI/H₃PO₄ solid solution.

According to yet another embodiment of the invention, the electrolyte is combined with a multilayer based on hydride materials capable of switching in light transmission or in light reflection, for which the switching is accompanied by the formation or the decomposition of hydrides.

It is formed in a manner similar to the all-solid glazing described above, namely it is composed of an active multilayer 3 placed between two current collectors 2 and 4 and it operates by insertion/extraction of H⁺ ions.

The active multilayer 3 is made up as follows:
a 20 to 100 nm layer made of a transition metal and in particular magnesium, to which another transition metal, and in particular nickel, cobalt or manganese, may be alloyed;
a layer according to the invention, that is to say that is to say the layer with a thickness of between 10 nm and 300 nm of silicon nitride, boron nitride, aluminum nitride or zirconium nitride, by itself or as a mixture, and optionally doped;
optionally, a palladium layer with a thickness of between 1 nm and 10 nm is inserted between the magnesium-based layer and the layer according to the invention;
a 100 nm layer made of a layer made of hydrated tantalum oxide or hydrated silica oxide or hydrated zirconium oxide or a mixture of these oxides; and
a 370 nm layer of cathodic electrochromic material based on hydrated tungsten oxide.

As a variant, a layer according to the invention is placed on either side of a palladium layer.

The active multilayer thus formed switches in reflection and in transmission, the change in appearance in reflection not being the same according to whether the observer looks at it from the hydride layer side or the tungsten oxide layer side.

When the potential difference to which the two electronically conductive layers 2 and 4 are subjected by the external power supply system (not shown) is such that the protons are predominantly in the tungsten oxide layer, the latter is colored and the magnesium-based layer is in a metallic and reflecting state. The light transmission of the glazing is less than 1% owing to the metallic state of the magnesium-based layer, which reflects most of the light.

Viewed in reflection on the magnesium-based layer side, the glazing is reflecting and slightly colored, with a light reflection of between 40% and 80%, depending on the thickness of the magnesium-based layer. When viewed in reflection on the tungsten oxide layer side, the glazing appears colored with a light reflection of between 5% and 20%, the color and the level of light reflection both depending on the thicknesses of the layers making up the multilayer and on the applied potential difference.

When the potential difference to which the two electronically conductive layers 2 and 4, which are associated with the current collectors via the external power supply system (not shown), are subjected is such that the protons are predominantly in the magnesium-based layer, the latter is in a semiconductive and bleached state and the tungsten oxide layer is in a bleached state. The light transmission of the glazing is a maximum, being between 20% and 50% depending on the thickness of the magnesium-based layer and on the presence of a palladium layer. The light reflection measured on the magnesium-based layer side is between 10% and 30%, as is the light reflection measured on the tungsten oxide layer side.

The changes in properties in reflection and in transmission within the visible wavelength range (380 nm-780 nm) mentioned in the above example are also valid in the infrared range (>780 nm), that is to say the energy reflection and transmission of the glazing vary in the same way as the light reflection and transmission.

Certain systems also have the feature of passing through an absorbent intermediate state, in which both light reflection and light transmission of the magnesium-based layer pass through a minimum.

Optionally, the magnesium-based hydride layer described above may be replaced with a hydride layer based on a rare earth (Gd, La, Y, etc.) optionally alloyed with a transition metal such as magnesium. One of the current collectors 2 and 4 mentioned in the example may be omitted, in particular that one in contact with the hydride layer if its electronic conductivity is high enough.

According to another application of the layer according to the invention, this is used in fuel cells as a medium for transporting ions, especially H⁺ or O²⁻.

1-22. (canceled)

23. An electrochemical system comprising at least one substrate, at least one electronically conductive layer, at least one electrochemically active layer capable of reversibly inserting cations of the H⁺, Li⁺, Na⁺, K⁺, Ag⁺ type or OH anions, and at least one layer having an electrolyte function, characterized in that the electrolyte is transparent in the visible and comprises at least one layer made of an essentially mineral material, in nonoxidized form, the ionic conduction of which is generated or enhanced by the incorporation of one or more of a hydrogenated or fluorinated nitride compound.

24. The electrochemical system as claimed in claim 23, characterized in that the layer having an electrolyte function is electronically insulating.

25. The electrochemical system as claimed in claim 23, characterized in that the absorption in the visible of the layer having an electrolyte function is less than 20% for a 100 nm film

26. The electrochemical system as claimed in claim 23, characterized in that said layer having an electrolyte function possesses a thickness of between 1 and 500 nm.

27. The electrochemical system as claimed in claim 23, characterized in that said layer having an electrolyte function is based on silicon nitride, boron nitride, aluminum nitride or zirconium nitride, by itself or as a mixture, and optionally doped.

28. The electrochemical system as claimed in claim 23, characterized in that said layer having an electrolyte function is a multilayer comprising, apart from the layer containing one or more nitrogen compounds, at least one other layer made of an essentially mineral material.

29. The electrochemical system as claimed in claim 28, characterized in that one of the other layers is selected from molybdenum oxide (WO₃), tantalum oxide (Ta₂O₅), antimony oxide (Sb₂O₅), nickel oxide (NiOₓ), tin oxide (SnO₂), zirconium oxide (ZrO₂), aluminum oxide (Al₂O₃), silicon oxide (SiO₂) niobium oxide (Nb₂O₅), chromium oxide (Cr₂O₃), cobalt oxide (CO₃O₄), titanium oxide (TiO₂), zinc oxide (ZnO), vanadium oxide (V₂O₅), optionally alloyed with aluminum, and tin zinc oxide (SnZnOₓ), at least one of these oxides being optionally hydrogenated or nitrided.

30. The electrochemical system as claimed in claim 23, characterized in that said layer having an electrolyte function is a multilayer comprising, apart from the layer containing one or more nitrogen compounds, at least one other layer made of a polymer material or one based on molten salts.

31. The electrochemical system as claimed in claim 30, characterized in that one of the other layers is selected from polymers possessing ionic conduction properties, optionally H⁺, Li⁺, Ag⁺, K⁺ and Na⁺.

32. The electrochemical system as claimed in claim 30, characterized in that the other layer of the polymer type is selected from the family of polyoxyalkylenes, optionally polyoxyethylene, or from the family of polyethyleneimines.

33. The electrochemical system as claimed in claim 30, characterized in that the other layer of the polymer type is in the form of an anhydrous or aqueous liquid or is based on one or more gels, or on one or more polymers, especially an electrolyte of the layer type comprising one or more hydrogen-containing and/or nitrogen-containing compounds of the POE:H₃PO₄ type or else a layer comprising one or more hydrogen-containing and/or nitrogen-containing compounds/PEI:H₃PO₄ or even more a laminatable polymer.

34. The electrochemical system as claimed in claim 23, characterized in that the electrochemically active layer comprises at least one of the following compounds: tungsten (W) oxide, niobium (Nb) oxide, tin (Sn) oxide, bismuth (Bi) oxide, vanadium (V) oxide, nickel (Ni) oxide, iridium (Ir) oxide, antimony (Sb) oxide, and tantalum (Ta) oxide, by itself or as a mixture, and optionally including an additional metal.

35. An electrochromic glazing, characterized in that it comprises the electrochemical system as claimed in claim 23, having in particular a variable light and/or energy transmission and/or reflection, with the substrate or at least part of the transparent or partially transparent substrate(s) made of glass or made of plastic, optionally mounted as multiple and/or laminated glazing, or as double glazing.

36. An electrochromic glazing, comprising the electrochemical system as claimed in claim 23, characterized in that it is combined with at least one other layer suitable for providing said glazing with an additional functionality.

37. An electrochromic glazing, incorporating a layer having an electrolyte function as claimed in claim 23, characterized in that said layer is associated with materials whose switching is accompanied by the formation or the decomposition of a hydride of Ti, V, Cr, Mn, Fe, Gd, Ni, Cu, Zn, Zr, Nb, Mo, Tc, Ru, Rh, Pd, Ag, Cd, Hf, Ta, W, Re, Os, Ir, Pt, Au, Hg or Mg, by itself or as a mixture, optionally alloyed with Gd.

38. A gas sensor, characterized in that it comprises the electrochemical system as claimed in claim 23.

39. A process for manufacturing the electrochemical device as claimed in claim 23, characterized in that the layer having an electrolyte function is deposited by a vacuum technique, of the cathode sputtering type, possibly magnetically enhanced sputtering, by thermal evaporation or electron beam evaporation, by laser ablation, by CVD, optionally plasma-enhanced or microwave-enhanced CVD, or by an atmospheric pressure technique, especially by layer deposition by sol-gel synthesis, especially of the dip coating, spray coating or flow coating type, or by atmospheric-pressure plasma CVD, or else by a powder or liquid-phase pyrolysis technique or a gas-phase pyrolysis technique of the CVD type but at atmospheric pressure.

40. The process as claimed in claim 39, characterized in that the layer having an electrolyte function containing nitrogen compounds is deposited by reactive sputtering in an atmosphere containing nitrogen compounds, or precursors of said compounds, optionally in the form of gaseous precursors.

41. A process for manufacturing an electrochemical system as claimed in claim 23, characterized in that at least one of the electrochemically active layers is deposited using a vacuum technique, especially by reactive sputtering or reactive magnetron sputtering, in DC, pulsed DC, AC or RF mode.

42. A method of using the glazing as claimed in claim 35 as windows for buildings, windows for automobiles, windows for commercial or rail, sea or air mass-transit vehicles, or as driving mirrors and other mirrors.

43. A method of using the glazing as claimed in claim 37 in equipment involving electronic and/or computing means and in equipment requiring an energy storage device which is intrinsic thereto, whether autonomous or not, particularly computers, televisions or telephones.

44. A method of using the gas sensor as claimed in claim 38, as control or monitoring means for physical, chemical, physico-chemical measurement instruments in an industrial, commercial or domestic environment.
